(19) United States
(12) Patent Application Publication
(10) Pub. No.: US 2007/0272974 A1
(43) Pub. Date: Nov. 29, 2007

(54) TWIN-GATE NON-VOLATILE MEMORY CELL AND METHOD OF OPERATING THE SAME

(75) Inventors: Ya-Chin King, Taoyuan County (TW); Chrong-Jung Lin, Taipei County (TW); Hsin-Ming Chen, Tainan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: EMEMORY TECHNOLOGY INC., Hsin-Chu (TW)

(21) Appl. No.: 11/752,250

(22) Filed: May 22, 2007

(30) Foreign Application Priority Data
May 23, 2006 (TW) 95118326
Mar. 9, 2007 (TW) 96108253

(51) Int. Cl. H01L 29/792

(52) U.S. Cl. 257/324

(57) ABSTRACT

A non-volatile memory cell with twin gates formed on an N-well is provided. The non-volatile memory cell includes at least a first gate, a second gate, a pair of NO (Nitride/Oxide) spacer layers, a pair of ONO (Oxide/Nitride/Oxide) spacers, a source, a drain, an extension source and an extension drain. The NO spacer layers are formed at the inner sidewalls of the first gate and the second gate to form a U-shape spacer for storing one bit of data. The ONO spacers are formed at the outer sidewalls of the first gate and the second gate. The source and drain and the extension source and the extension drain have P-type impurity dopants.

### CROSS-REFERENCE TO RELATED APPLICATION

This application claims the priority benefits of Taiwan applications serial no. 95118326, filed May 23, 2006 and serial no. 96108253, filed Mar. 9, 2007. All disclosures of the Taiwan applications are incorporated herein by reference.

### BACKGROUND OF THE INVENTION

1. Field of the Invention

The present invention generally relates to a non-volatile memory structure, more particularly, to a CMOS process compatible twin-gate non-volatile memory and method of operating the same.

2. Description of Related Art

Flash memory disk is one kind of non-volatile storage device that requires no electrical power to retain the data stored therein. Furthermore, a typical memory cell is capable of storing the data for at least 10 years. Unlike a hard disk storage device that requires a stepping motor to drive a read/write magnetic head over a disk to access the data, for example, to magnetize (write) a small magnetic region or determine (read) the magnetized state of a small magnetic region, there is no electromechanical motion in the flash memory disk. Data in the flash memory disk can be access by applying different voltages to the electrodes of the device. Since no stepping motor is used, the flash memory disk has no mechanical vibration problem. Furthermore, with advance in semiconductor process, the volume of flash memory disk is substantially smaller than a hard disk. Because of extreme portability, flash memory disk has been broadly applied to memory disk, MP3 disk, personal digital assistant (PDA) and mobile phone. In addition, the memory storage capacity of the foregoing devices can be further expanded by adding memory cards formed out of flash memory

A typical flash memory cell includes a control gate, a floating gate, a source and a drain. In general, when electrons are trapped by the oxide-surrounded floating gate in the process of programming the floating gate, then the memory cell is regarded as having a binary bit value ‘0’. When no electrons are trapped inside the floating gate in the process of programming the floating gate, then the memory cell is regarded as having a binary bit value ‘1’.

The capacity of the flash memory disk is obviously related to how many flash memory chips are stacked together and the capacity of single memory chip is obviously related to the processing technique of semiconductors. By moving to more advanced technologies, the semiconductor devices can be scaled down accordingly. For example, if the flash device unit's dimension is scaling down by a half, the memory storage capacity can increase four times. The capability of current semiconductor process to fabricate a Giga-byte capacity chip that exceeds earlier 5-inch hard disk is nothing new. However, hard disk memory devices also progresses from the 2.5-inch hard disk of a notebook computer to today's micro hard disk (having a diameter of only 1 inch), which is equipped with a storage capacity reaching several tens of Giga-bytes.

To prevent flash memory disk from losing ground in the battle of competition with hard disk storage devices, semiconductor process engineers are working hard to look for innovative scaling down techniques while device design engineers are also searching for better memory device structures. Recently, the so-called SONOS (Semiconductor-Oxide-Nitride-Oxide-Semiconductor) structure as an element of flash memory is an example of a successful story for a better memory device structure. FIGS. 1A and 1B show a conventional split-gate flash memory and a stacked gate flash memory, respectively. The split-gate flash memory and the stacked gate flash memory have one common characteristic: namely, they both have floating polysilicon gates 10. Regardless of whether the floating polysilicon gate 10 contains doped conductive impurities or not, the electrons injected in a programming operation are evenly distributed inside the floating polysilicon gate 10. Therefore, each flash memory cell can only store a single bit of data.

FIG. 1C shows another conventional stacked gate flash memory. As shown in FIG. 1C, this newer SONOS (semiconductor/oxide/nitride/oxide/semiconductor) flash memory cell 20 has a different structure. A silicon nitride layer 23 replaces the polysilicon layer. Because oxide layers 22 and 24 are disposed above and below the silicon nitride layer 23, this structure looks like a conventional transistor with an ONO composite layer replacing the O layer. When electrons tunnel through the oxide layer 22 into the silicon nitride layer 23, the electrons lose their mobility almost completely. Instead of distributing evenly within the polysilicon layer, the electrons inside the silicon nitride layer 23 are localized. If the electrons are injected from the source 21, the electrons are stored on side 23a of the nitride layer 23 close to the source 21. On the other hand, if the electrons are injected from the drain 25, the electrons are stored on side 23b of the nitride layer 23 close to the drain 25. In other words, each memory device having the same semiconductor process dimensions can record two bits of data. Therefore, the memory storage capacity is doubled.

One of the advantages of using the SONOS structure is that there are no error bits (tail or fly bits) that are detached from the normal group distribution because the electrical charges are stored inside in the silicon nitride layer 23 and confined by a trap. Therefore, the movement of electrical charges from one trap to another is difficult. Furthermore, if a defect exists somewhere in the oxide layer underneath the silicon nitride layer 23, the probability of electrical charges trapped at a far end moving all the way to the defect is low. Consequently, unlike the floating gate, which is a conductor that allows the electrical charges freedom of movement and increases group leakage and the so-called ‘unreliable error bits’, the SONOS structure has no such problems.

Another flash memory cell that can store two bits in a single device structure can be found in another ROC Patent No. 95116153 applied in May 5, 2006. The main structure of the device is shown in FIG. 1D. The memory cell structure in FIG. 1D is formed in an n-well NW and includes forming two ONO spacers 120 on the sidewalls of the p-type transistor. The polarity of the conductive impurities in the source/drain 130A and 130B is opposite to that of the extension source/drain 125A and 125B. Consequently, the source 130A is connected to the drain 130B is determined by whether electrons are stored in the nitride layer 120A or 120B. To read data from the memory cell, different voltages are selected and applied to the source/drain 130A and 130B so as to turn on the main channel under the gate 110 and select to read either the left memory cell 105L or the right memory cell 105R.

The present invention discloses another memory structure quite similar to the one in FIG. 1D. However, the present invention utilizes the spacers between two gates to store the data. Refer to the following embodiment for a more detailed description.

### SUMMARY OF THE INVENTION

Accordingly, the present invention is directed to a twin-gate non-volatile memory cell formed on a second conductive type impurity substrate. The twin-gate non-volatile memory cell includes at least a first gate, a second gate, a pair of spacer layers, a pair of spacers, a source, a drain, an extension source and an extension drain. The first gate and the second gate are formed on the second conductive type impurity substrate. The spacer layers are formed on the inner sidewalls of the first gate and the second gate, respectively, and are connected to each other. The spacer layers include a dielectric layer and a non-conductive charge storage layer and can store one bit of data. The spacers are formed on the outer sidewalls of the first gate and the second gate, respectively. The source and the drain are heavily doped first conductive type impurity regions formed in the second conductive type impurity substrate and outside the edge of the first gate and the second gate, respectively. The extension source and the extension drain are lightly doped first conductive type impurity regions formed in the second conductive type impurity substrate and between the first gate and the source and between the second gate and the drain, respectively.

In an embodiment of the present invention, the second conductive type impurities are N-type impurities and the first conductive type impurities are P-type impurities. The spacer layers include a U-shape spacer layer or a rectangular-shape spacer layer. The spacer layers include an oxide/nitride layer, an oxide/oxynitride layer, or a high dielectric constant material/nitride layer. The second conductive type impurity substrate under the spacer layers has neither doped impurities of the source and the drain nor doped impurities of the extension source and the extension drain. The foregoing substrate is an NW formed on Si-substrate, SOI-substrate, Glass-substrate etc.

In an embodiment of the present invention, the first conductive type impurities are N-type impurities and the second conductive type impurities are P-type impurities. The foregoing substrate is a P-well.

The present invention also disclosed a method of operating a twin-gate non-volatile memory cell, wherein the twin-gate non-volatile memory cell includes a first gate, a second gate, charge-trapping layers, a source and a drain. The first gate and the second gate are formed on a second conductive type impurity substrate, and the charge-trapping layers are formed on the inner sidewalls of the first gate and the second gate, respectively, and connected to each other. Furthermore, the charge-trapping layers can store at least one bit of data. The source and the drain are heavily doped first conductive type impurity regions formed in the second conductive type impurity substrate and outside the edge of the first gate and the second gate, respectively. The method of programming the twin-gate non-volatile memory cell includes initiating a source-side induced hot carrier injection (SSI) so as to inject electrons into the charge-trapping layers.

In an embodiment of the present invention, the first conductive type impurities are P-type impurities and the second conductive type impurities are N-type impurities. The programming method includes applying a first voltage to the substrate; applying a second voltage, which is negative with respect to the substrate, to the drain; applying a third voltage, which is negative with respect to the substrate, to the first gate so as to form a conductive channel under the first gate; applying a fourth voltage, which is negative with respect to the substrate, to the second gate so as to form a conductive channel under the second gate; and applying a fifth voltage, which does not form a junction forward bias with the substrate, to the source. The voltage setting in each electrode must be able to generate SSI effect so as to inject electrons into the charge-trapping layers.

In an embodiment of the present invention, the voltage difference between the second voltage and the first voltage is about −5V, the voltage difference between the third voltage and the first voltage is about −1.5V, the voltage difference between the fourth voltage and the first voltage is about −5V, and the voltage difference between the fifth voltage and the first voltage is about 0V.

In an embodiment of the present invention, the first voltage is about 0V, the second voltage is about −5V, the third voltage is about −1.5V, the fourth voltage is about −5V and the fifth voltage is about 0V.

In an embodiment of the present invention, a sixth voltage, which is identical to the voltage of the substrate, is applied to the drain, and a seventh voltage, which does not form a junction forward bias with the substrate, is applied to the drain when the twin-gate non-volatile memory cell is not being programmed. The voltage difference between the seventh voltage and the first voltage is about 0V.

In an embodiment of the present invention, the first voltage is about 0V, the sixth voltage is about 0V and the seventh voltage is about 0V.

In an embodiment of the present invention, reading data from the twin-gate non-volatile memory cell includes applying an eighth voltage to the substrate; applying a ninth voltage, which is negative with respect to the substrate, to the drain; applying a tenth voltage, which is negative with respect to the substrate, to the first gate so as to form a conductive channel under the first gate; applying an eleventh voltage, which is negative with respect to the substrate, to the second gate so as to form a conductive channel under the second gate; and applying a twelfth voltage, which does not form a junction forward bias with the substrate, to the source. The voltage setting of each electrode must be able to suppress the SSI effect.

In an embodiment of the present invention, the voltage difference between the ninth voltage and the eighth voltage is about −1.5V, the voltage difference between the tenth voltage and the eighth voltage is about −2.5V, the voltage difference between the eleventh voltage and the eighth voltage is about −2.5V, and the voltage difference between the twelfth voltage and the eighth voltage is about 0V.

In an embodiment of the present invention, the eighth voltage is about 0V, the ninth voltage is about −1.5V, the tenth voltage is about −2.5V, the eleventh voltage is about −2.5V, and the twelfth voltage is about 0V.

In an embodiment of the present invention, erasing data from the twin-gate non-volatile memory cell includes using the Fowler-Nordheim (FN) method to drive electrons out of the charge-trapping layers.

In an embodiment of the present invention, the FN erasing method includes floating the source and the drain; applying a thirteenth voltage to the substrate, applying a fourteenth voltage, which is negative with respect to the substrate, to the first gate; and applying a fifteenth voltage, which is negative with respect to the substrate, to the second gate. The voltage setting of each electrode must be able to initiate the FN effect so as to drive electrons out of the charge-trapping layers.

In an embodiment of the present invention, the voltage difference between the fourteenth voltage and the thirteenth voltage is about −10V, and the voltage difference between the fifteenth voltage and the thirteenth voltage is about −10V.

In an embodiment of the present invention, the thirteenth voltage is about 5V, the fourteenth voltage is about −5V and the fifteenth voltage is about −5V.

In an embodiment of the present invention, the first conductive type impurities are N-type impurities and the second conductive type impurities are P-type impurities. The programming method includes applying a first voltage to the substrate; applying a second voltage, which is positive with respect to the substrate, to the drain; applying a third voltage, which is positive with respect to the substrate, to the first gate so as to form a conductive channel under the first gate; applying a fourth voltage, which is positive with respect to the substrate, to the second gate so as to form a conductive channel under the second gate; and applying a fifth voltage, which does not form a junction forward bias with the substrate, to the source. The voltage setting in each electrode must be able to generate the SSI effect so as to inject electrons into the charge-trapping layers.

In an embodiment of the present invention, the voltage difference between the second voltage and the first voltage is about 5V, the voltage difference between the third voltage and the first voltage is about 1.5V, the voltage difference between the fourth voltage and the first voltage is about 5V, and the voltage difference between the fifth voltage and the first voltage is about 0V.

In an embodiment of the present invention, the first voltage is about 0V, the second voltage is about 5V, the third voltage is about 1.5V, the fourth voltage is about 5V and the fifth voltage is about 0V.

In an embodiment of the present invention, a sixth voltage, which is identical to the voltage of the substrate, is applied to the drain; and a seventh voltage, which does not form a junction forward bias with the substrate, is applied to the drain when the twin-gate non-volatile memory cell is not being programmed. The voltage difference between the seventh voltage and the first voltage is about 0V.

In an embodiment of the present invention, the first voltage is about 0V, the sixth voltage is about 0V and the seventh voltage is about 0V.

In an embodiment of the present invention, reading data from the twin-gate non-volatile memory cell includes applying an eighth voltage to the substrate; applying a ninth voltage, which is positive with respect to the substrate, to the drain; applying a tenth voltage, which is positive with respect to the substrate, to the first gate so as to form a conductive channel under the first gate; applying an eleventh voltage, which is positive with respect to the substrate, to the second gate so as to form a conductive channel under the second gate; and applying a twelfth voltage, which does not form a junction forward bias with the substrate, to the source. The voltage setting of each electrode must be able to suppress the SSI effect.

In an embodiment of the present invention, the voltage difference between the ninth voltage and the eighth voltage is about 1.5V, the voltage difference between the tenth voltage and the eighth voltage is about 2.5V, the voltage difference between the eleventh voltage and the eighth voltage is about 2.5V, and the voltage difference between the twelfth voltage and the eighth voltage is about 0V.

In an embodiment of the present invention, the eighth voltage is about 0V, the ninth voltage is about 1.5V, the tenth voltage is about 2.5V, the eleventh voltage is about 2.5V, and the twelfth voltage is about 0V.

In an embodiment of the present invention, erasing data from the twin-gate non-volatile memory cell includes using the FN method to drive electrons out of the charge-trapping layers.

In an embodiment of the present invention, the FN erasing method includes floating the source and the drain; applying a thirteenth voltage to the substrate; applying a fourteenth voltage, which is negative with respect to the substrate, to the first gate; and applying a fifteenth voltage, which is negative with respect to the substrate, to the second gate. The voltage setting of each electrode must be able to initiate the FN effect so as to drive electrons out of the charge-trapping layers.

In an embodiment of the present invention, the voltage difference between the fourteenth voltage and the thirteenth voltage is about −10V, and the voltage difference between the fifteenth voltage and the thirteenth voltage is about −10V.

In an embodiment of the present invention, the thirteenth voltage is about 5V, the fourteenth voltage is about −5V and the fifteenth voltage is about −5V.

In the method of operating the twin-gate non-volatile memory of the present invention, the drain is the electrode that determines whether a ‘1’ or a ‘0’ is programmed into the memory cell when the twin-gate non-volatile memory cell is programmed. Meanwhile, a suitable voltage can be applied to the first gate and the second gate, and a 0V can be applied to the well and the source. The drain voltage can be increased or decreased according to the whether the programming efficiency meets the system requirements. The voltages applied to the first gate, the second gate and the drain must be high enough to generate a sufficiently large horizontal electric field under the spacer layers so that the impact ionization by the electrical charges is able to produce extra electron-hole pairs. Moreover, the application of a suitable voltage to the first and the second gate can generate a sufficiently large vertical electric field to induce the electrons to turn and move toward the charge-trapping spacer layers, and ultimately captured by the trap within the charge-trapping layers.

The method of programming the twin-gate non-volatile memory cell of the present invention can be viewed as a requirement for the voltage applied to the first gate being able to turn on the channel under the first gate and transmit the source voltage (0V) to the channel close to the first gate and under the spacers. In other words, a smaller first gate voltage can be applied, and the requirement for the voltage applied to the second gate is to turn on the channel under the second gate and transmit the drain voltage to the channel close to the second gate and under the spacer. Therefore, utilizing the short distance between the ends of the channel under the U-shape spacers between the first gate and the second gate and the application of a sufficiently large voltage difference between the two ends, a large horizontal electric field is created within a short distance so as to form the so-called ‘Source-Side induced hot carriers Injection’ for injecting electrical charges into the charge-trapping layers within the spacers. In addition, because the voltage applied to the first gate is small, the programming current required in the programming operation can be ultra low. This is one important advantage in the design of memory circuits.

In the method of operating the twin-gate non-volatile memory cell of the present invention, the voltage applied to the first gate and the second gate for reading data from the memory cell need not be too large. The voltage only serves to turn on the channel under the second gate.

In the method of operating the twin-gate non-volatile memory cell of the present invention, the FN erasing method is used to remove the electrons in the charge-trapping layers within the U-shape spacers so as to erase data from the non-volatile memory cell.

In order to make the aforementioned and other objects, features and advantages of the present invention comprehensible, preferred embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a schematic cross-sectional view of a conventional split-gate flash memory.

FIG. 1B is a schematic cross-sectional view of a conventional stacked gate flash memory.

FIG. 1C is a schematic cross-sectional view of a conventional SONOS flash memory.

FIG. 1D is a schematic cross-sectional view of a conventional non-volatile memory having SONOS grown on sidewalls.

FIG. 2A is a schematic cross-sectional view of a twin-gate non-volatile memory cell formed according to a method of the present invention.

FIG. 2B shows a twin-gate non-volatile memory cell being programmed according to a first preferred embodiment of the present invention.

FIG. 2C shows data being read from a twin-gate non-volatile memory according to a first preferred embodiment of the present invention.

FIG. 2D shows an FN erasing operation being performed to remove electrons from a nitride layer so as to erase data from a twin-gate non-volatile memory cell according to a first preferred embodiment of the present invention.

FIG. 3 is a schematic cross-sectional view of a twin-gate non-volatile memory cell with N-type dopants in the source and the drain according to a second preferred embodiment of the present invention.

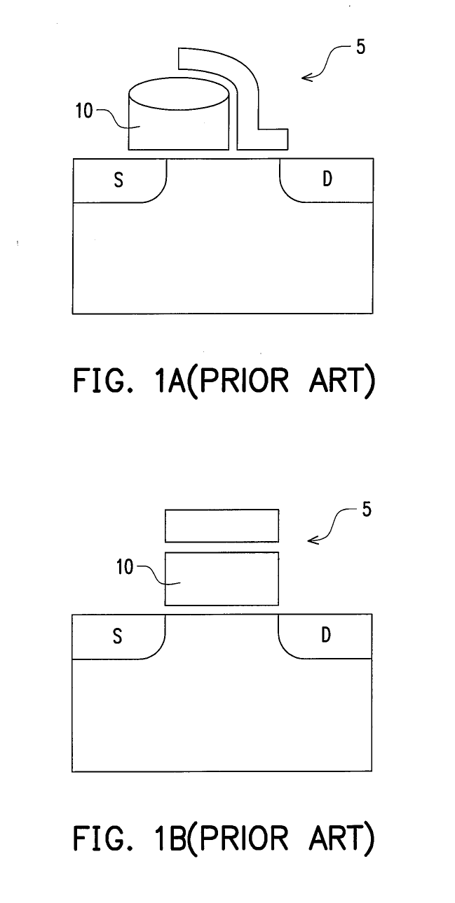

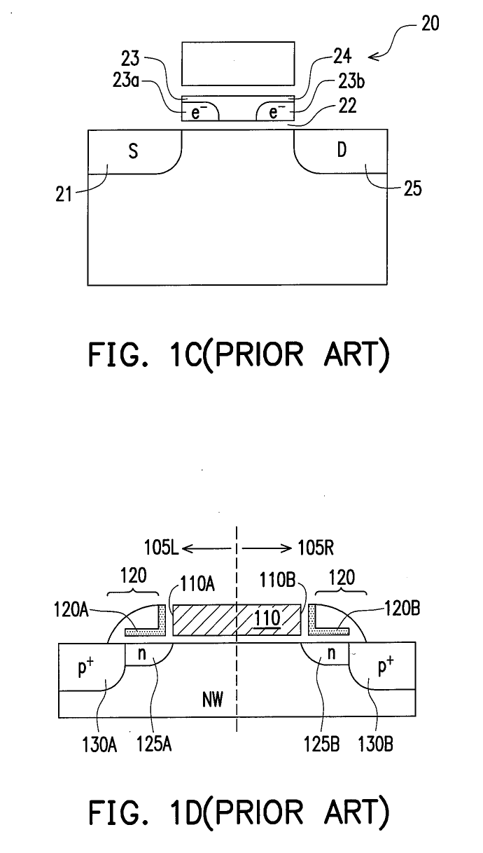

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

The present invention discloses a new non-volatile memory cell compatible to a logic CMOS (complementary metal-oxide-semiconductor) process. This non-volatile memory cell includes inner spacers between the two polysilicon gates of a twin-gate transistor. The inner spacers is formed by NO (nitride layer, oxide layer) material. Because the spacers are connected, they form a U-shape structure. From now on, this type of memory cell is referred to as a twin-gate non-volatile memory cell. By using the twin gates as control gates, the operating speed of the memory is increased.

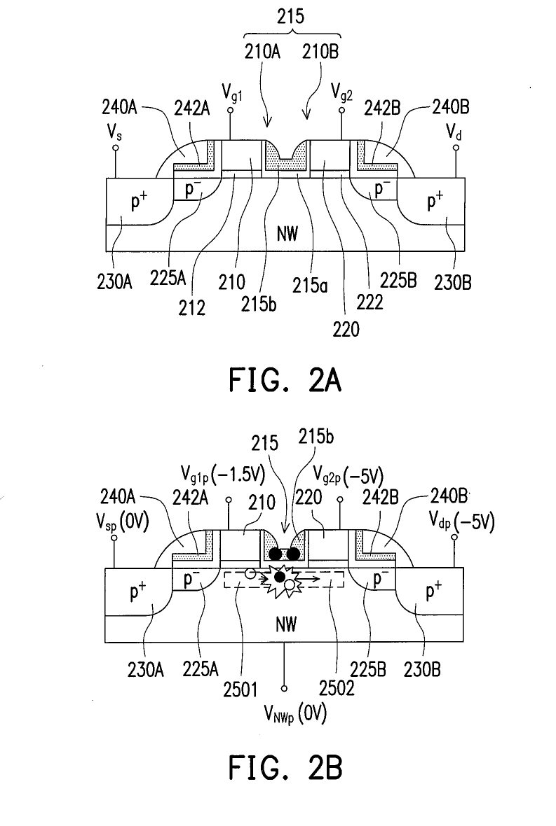

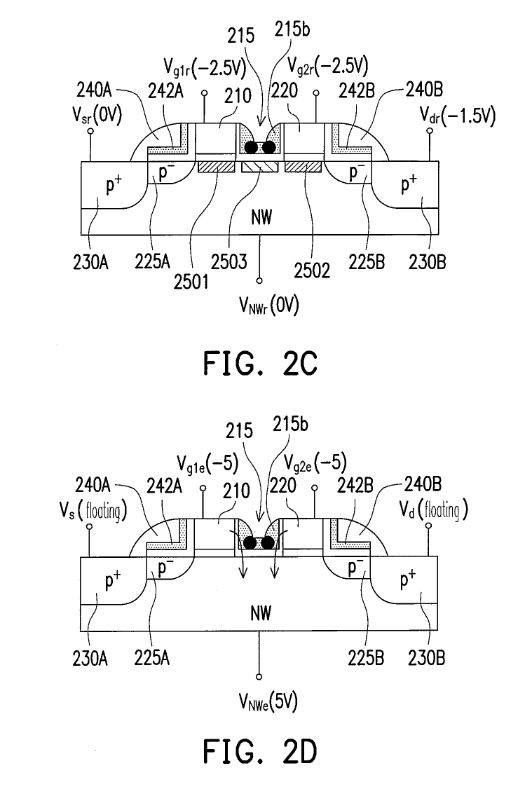

The twin-gate non-volatile memory cell is built in an n-well (NW) of logic CMOS process. FIG. 2A is a schematic cross-sectional view of a twin-gate non-volatile memory cell. The twin-gate non-volatile memory cell includes a first gate 210, a second gate 220, a spacer layer 215, spacers 240A, 240B, an extension source 225A, an extension drain 225B, a source 230A and a drain 230B.

The first gate 210 and the second gate 220 are formed on a substrate (an n-well). The material of the first gate 210 and the second gate 220 can be metal, doped polysilicon or polysilicon silicide (polycide). Gate dielectric layers 212 and 222 are formed between the first gate 210 and the n-well (the substrate) and between the second gate 220 and the n-well (the substrate), respectively. The material of the gate dielectric layers 212 and 222 includes high dielectric constant material with a dielectric constant greater than 4, silicon oxide or silicon nitride. The gate dielectric layers 212 and 222 can be dielectric material layers composed of one or more layers.

A pair of spacers 210A and 210B is formed on the inner sidewalls of the first gate 210 and the second gate 220, respectively, and the spacers 210A and 210B are connected together. In other words, a spacer layer 215 is formed by connecting the spacers 210A and 210B on the opposing inner sides of the first gate 210 and the second gate 220, respectively. As shown in FIG. 2A, the shape of the spacer layer 215 is a U-shape, for example. Obviously, the U-shape is only a common name of the visual appearance. The shape of the layer formed on the inner sidewalls between the first gate 210 and the second gate 220 is substantially related to the distance between the two gates and the composition of the spacers. However, the most important concept is that a spacer layer formed naturally between two gates has a dielectric layer 215a and a charge-trapping layer 215b. Of course, the spacer layer 215 can have other shape such as a rectangular shape, which depends on the method of forming the spacer layer 215 and the distance between the first gate 210 and the second gate 220. The material of the charge-trapping layer 215b includes a material having charge-trapping ability, for example, silicon nitride, silicon oxynitride, nano-crystal, silicon tantalum oxide, silicon strontium titanate or silicon hafnium oxide. The dielectric layer 215a is disposed between the charge-trapping layer 215b and the n-well (substrate), the first gate 210 and the second gate 220 so as to isolate the charge-trapping layer 215b from the n-well, the first gate 210 and the second gate 220. The material of the dielectric layer 215a includes, for example, silicon oxide or a high dielectric constant material with a dielectric constant greater than 4 such as tantalum oxide (Ta₂O₅), aluminum oxide (Al₂O₃), hafnium oxide (HfO₂), hafnium silicon oxynitride (HfSiON), hafnium silicon oxide (HfSiO₂) and hafnium aluminum silicon oxide (HfAlSiO₂). In the present embodiment, the spacer layer 215 is a silicon oxide (dielectric layer 215a)/silicon nitride (charge-trapping layer 215b) composition layer, for example. Obviously, the spacer layer 215 can be fabricated using other materials such as silicon oxide/silicon oxynitride layer or high dielectric constant material/silicon nitride layer.

The pair of spacers 240A and 240B is formed on the outer sidewalls of the first gate 210 and the second gate 220, respectively. The material of the spacers 240A and 240B is, for example, oxide/nitride/oxide (ONO). In the ONO spacers 240A and 240B, the silicon nitride layers 242A and 242B are mirrored L-shape and L-shape, respectively. Obviously, the spacers 240A and 240B can be fabricated using other insulating materials.

The source 230A and the drain 230B are formed in the substrate (the n-well) and outside the edge of the first gate 210 and the second gate 220, respectively. The extension source 225A and the extension drain 225B are formed in the substrate (the n-well) between the first gate 210 and the source 230A and between the second gate 220 and the drain 230B, respectively. In addition, the extension source 225A, the extension drain 225B, the source 230A and the drain 230B are P-type conductive impurity doped regions. As in a normal transistor, the source 230A and the drain 230B are heavily doped regions and the extension source 225A and the extension drain 225B are lightly doped regions. The n-well is an n-type conductive impurity doped region with a doping lighter than the lightly doped region. The spacer layer 215 is capable of storing at least one bit of data.

In the foregoing preferred embodiment, there is no impurities of source 230A/drain 230B nor extension source 225A/extension drain 225B in the conductive impurity substrate under the spacer layer 215. In other words, a photoresist layer on the spacer layer 215 can be used to prevent ions from being implanted into the conductive type impurity substrate under the spacer layer 215 in the ion implantation for forming the source 230A/drain 230B or the extension source 225A/extension drain 225B so that unexpected and unruly areas are not formed.

The foregoing description shows the structure of the twin-gate non-volatile memory cell. In the following, a method of operating the twin-gate non-volatile memory cell is described.

In the present invention, a Source-Side induced hot carriers Injection (SSI) can be used to program the twin-gate non-volatile memory cell into a bit state ‘1’ (binary). The electrodes and their bias voltages are shown in FIG. 2B. A voltage V_{NWP} is applied to the NW body (substrate); a voltage V_{dp}, which is negative with respect to the NW body (substrate), is applied to the drain 230B; a voltage V_{g1p}, which is negative with respect to the NW body (substrate), is applied to the first gate 210 so as to form a conductive channel under the first gate 210; a voltage V_{g2p}, which is negative with respect to the NW body (substrate), is applied to the second gate 220 so as to form a conductive channel under the second gate 220; and a voltage Vₛₚ which does not form a junction forward bias with the NW body (substrate) is applied to the source 230A. The settings of the voltages V_{NWP}, V_{dp}, V_{g1p}, V_{g2p} and Vₛₚ must be able to generate the SSI effect so as to inject electrons into the charge-trapping layer 215b.

The voltage difference between V_{dp} and V_{NWP} is about −5V; the voltage difference between V_{g1p} and V_{NWP} is about −1.5V; the voltage difference between V_{g2p} and V_{NWP} is about −5V; and, the voltage difference between Vₛₚ and V_{NWP} is about 0V. In the present embodiment, the voltage of V_{NWP} is about 0V; the voltage of V_{dp} is about −5V; the voltage of V_{g1p} is about −1.5V; the voltage of V_{g2p} is about −5V; and, the voltage of Vₛₚ is about 0V, for example.

Obviously, all the voltages applied to the electrodes can be shifted to fit the requirements of a particular circuit design. For example, all the voltages can be up-shifted by 5V to form the following settings: a voltage V_{NWP} (5V) is applied to the NW body, a voltage Vₛₚ (5V) is applied to the source 230A, a voltage V_{g1p} (3.5V) is applied to the first gate 210, a voltage V_{g2p} (0V) is applied to the second gate 220 and a voltage V_{dp} (0V) is applied to the drain 230B. Because a voltage is not applied to the spacer layer 215, the probability of forming an inversion layer through an externally applied voltage is very small. Therefore, the voltage Vₛₚ (0V) of the source 230A and the voltage V_{g1p} (−1.5V) of the first gate 210 can only affect the end of the first channel 2501 (the rightmost end of the first channel 2501 in FIG. 2B), and the voltage V_{dp} (−5V) of the drain 230B and the voltage V_{g2p} (−5V) of the second gate 220 can only affect the end of the second channel 2502 (the leftmost end of the second channel 2502 in FIG. 2B). Furthermore, the drain 230B and the NW body are reverse bias. Therefore, due to the closeness of the positive charges (hole carriers) at the end of the first channel 2501 to the N-type substrate under the spacer layer 215, a horizontal electric field is generated. The strength of the electric field is related to the drain 230B voltage V_{dp} and the length of the spacer layer 215. When the voltage V_{dp} is sufficiently negative, holes will be accelerated by the electric field and impact the silicon crystal lattice to produce more electron-hole pairs. Since electrons can tunnel through the energy barrier of the oxide layer in the spacer layer 215 more readily than holes, electrons are trapped by the charge-trapping layer 215b so that programming the memory cell to a logic state ‘1’ is achieved.

Obviously, if the memory cell needs to be programmed to a logic state ‘0’, in other words, the foregoing twin-gate non-volatile memory cell are not programmed, a voltage V_{NWP} is applied to the NW body (substrate), a voltage V_{d0}, which is identical to the voltage applied to the NW body (substrate), is applied to the drain, a voltage Vₛ₀, which does not form a junction forwards bias with the NW body (substrate), is applied to the source. The voltage difference between the voltage Vₛ₀ and the voltage V_{NWP} is about 0V. The voltage V_{NWP} is about 0V; the voltage V_{d0} is about 0V; and, the voltage Vₛ₀ is about 0V.

When data need to be read from the twin-gate non-volatile memory cell, the electrodes and their bias voltages are shown in FIG. 2C. As shown in FIG. 2C, a voltage V_{NWr} is applied to the NW body (substrate); a voltage V_{dr}, which is negative with respect to the NW body (substrate), is applied to the drain 230B; a voltage V_{g1r}, which is negative with respect to the NW body (substrate), is applied to the first gate 210 so as to form a conductive channel under the first gate 210; a voltage V_{g2r}, which is negative with respect to the NW body (substrate), is applied to the second gate 220 so as to form a conductive channel under the second gate 220; and, a voltage Vₛᵣ, which does not form a junction forward bias with the NW body (substrate) is applied to the source 230A.

The voltage difference between the voltage V_{dr} and the voltage V_{NWr} is about −1.5V; the voltage difference between the voltage V_{g1r} and the voltage V_{NWr} is about −2.5V; the voltage difference between the voltage V_{g2r} and the voltage V_{NWr} is about −2.5V; the voltage difference between the voltage Vₛᵣ and the voltage V_{NWr} is about 0V. The voltage V_{NWr} is about 0V; the voltage V_{dr} is about −1.5V; the voltage V_{g1r} is about −2.5V; the voltage V_{g2r} is about −2.5V; and, the voltage Vₛᵣ is about 0V, for example. The voltage V_{NWr} applied to the NW body (substrate), the voltage V_{g1r} applied to the first gate 210 and the voltage Vₛᵣ applied to the source 230A when reading data are identical to the voltage V_{NWP} applied to the NW body (substrate), the voltage V_{g1p} applied to the first gate 210 and the voltage Vₛₚ applied to the source 230A when programming data into the memory, respectively. However, the voltage V_{g2r} applied to the second gate 220 and the voltage V_{dr} applied to the drain 230B when reading data must be substantially smaller than the voltage V_{g2p} applied to the second gate 220 and the voltage V_{dp} applied to the drain 230B when programming data into the memory, respectively. The settings of the voltage V_{g1r} and the voltage V_{g2r} are made only to ensure the channel under the first gate and the second gate conductive, and the setting of the voltage V_{dr} is made to allow the flow of a channel current due to the voltage difference between the drain and the source. In other words, the settings of the voltage V_{g1r} and the voltage V_{g2r} only have to ensure that the first channel 2501 and the second channel 2502 are conductive (with an inversion layer) while a third channel 2503 under the spacer layer 215 is conductive or not is determined by whether electrons are trapped inside the charge-trapping layer 215b. When the memory cell is programmed to a logic state ‘1’, electrons are trapped so that a negative vertical electric field is generated to produce an inversion layer in the third channel 2503. Hence, the third channel 2503 is conductive and a hole current flowing from the source 230A to the drain 230B can be read. Otherwise, the third channel 2503 is non-conductive and no trapped electrons in the charge-trapping layer 215b are implied.

When data need to be erased from the twin-gate non-volatile memory cell, the electrodes and their bias voltages are shown in FIG. 2D. As shown in FIG. 2D, a voltage V_{NWe} is applied to the NW body (substrate), the source 230A is floating, a voltage V_{g1e}, which is negative with respect to the NW body (substrate), is applied to the first gate 210, a voltage V_{g2e}, which is negative with respect to the NW body (substrate), is applied to the second gate 220 and the drain 230B is floating. The settings of the voltage V_{NWe}, the voltage V_{g1e} and the voltage V_{g2e} must be able to initiate a FN erasing operation for driving electrons out of the charge-trapping layer. The voltage difference between the voltage Vg1e and the voltage V_{NWe} is about −10V and the voltage difference between the voltage V_{g2e} and the voltage V_{NWe} is about −10V. In the present embodiment, the voltage V_{NWe} is about 5V, the voltage V_{g1e} is about −5V, and the voltage V_{g2e} is about −5V, for example. Accordingly, the FN effect is utilized to erase the electrons in the spacer layer 215. In other words, by applying voltage V_{NWe} (5V) and negative voltage V_{g1e} (−5V) and V_{g2e} (−5V), the repulsion between electrons and a negative voltage can be utilized to drive out the electrons within the charge-trapping layer 215b of the spacer layer 215 and guide them toward the n-well.

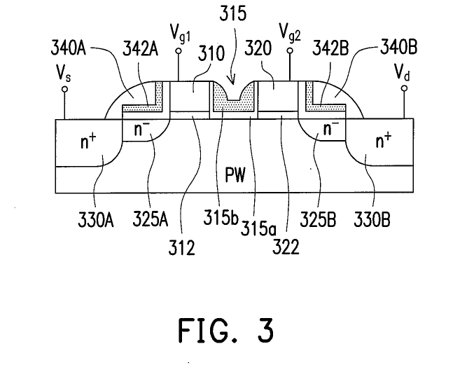

In the foregoing preferred embodiment, a twin-gate non-volatile memory cell with a P-type channel is used as an example. However, this example should not be used to limit the claims of the present invention. For example, the present invention is also applicable to a twin-gate non-volatile memory cell with an N-type channel as shown in FIG. 3.

The N-channel twin-gate non-volatile memory cell shown in FIG. 3 is basically identical to the aforementioned P-channel twin-gate non-volatile memory cell. The main difference is that the memory cell is formed on a P-type well (PW) and has an N-doped source 330A, an N-doped drain 330B, an N-doped extension source 325A and an N-doped extension drain 325B. The voltages for operating the N-channel twin-gate non-volatile memory cell are basically not completely identical to the voltages for operating the P-channel twin-gate non-volatile memory. Table 1 is a table for comparing the applied bias voltages between the P-channel and the N-channel twin-gate non-volatile memory cell when performing a programming operation, a reading operation and an erasing operation.

TABLE 1

| | | p-type channel | n-type channel |
|---|---|---|---|
| Programming | Source Vₛₚ | 0 V | 0 V |
| Method | First gate V_{g1p}, | Negative Voltage | Positive Voltage |
| | Second gate V_{g2p} | | |
| | Drain V_{dp} | Negative Voltage | Positive Voltage |
| | N-well V_{NWP} or | 0 V | 0 V |
| | P-well V_{PWP} | | |
| Reading | Source Vₛᵣ | 0 V | 0 V |
| | First gate V_{g1r}, | Negative Voltage | Positive Voltage |
| | Second gate V_{g2r} | | |
| | Drain V_{dr} | Negative Voltage | Positive Voltage |
| Erasing | Source Vₛ | Floating | Floating |
| Method | First gate V_{g1e}, | Negative Voltage | Negative Voltage |
| | Second gate V_{g2e} | | |
| | Drain V_{d} | Floating | Floating |
| | N-well V_{NWe} or | 0 V | 0 V |
| | P-well V_{PWe} | | |

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A twin-gate non-volatile memory cell formed on a second conductive type impurity substrate, comprising:
a first gate and a second gate formed on the second conductive type impurity substrate;
a pair of spacer layers formed on inner sidewalls of the first gate and the second gate, respectively, and connected to each other, wherein the spacer layers comprise a dielectric layer and a non-conductive charge-storage layer, and the spacer layers store at least one bit of data;
a pair of spacers formed on outer sidewalls of the first gate and the second gate, respectively;
a source and a drain of doped first conductive type impurities formed in the second conductive type impurity substrate and outside and underneath an edge of the first gate and the second gate, respectively.

2. The twin-gate non-volatile memory cell according to claim 1, wherein the second conductive type impurities are N-type impurities and the first conductive type impurities are P-type impurities.

3. The twin-gate non-volatile memory cell according to claim 1, wherein the substrate can be a Si-substrate, SOI substrate or Glass substrate.

4. The twin-gate non-volatile memory cell according to claim 1, wherein the spacer layers comprises an oxide/nitride/oxide layer, an oxide/oxynitride layer, an oxide/nano-crystal layer or a high dielectric constant material/nitride layer.

5. The twin-gate non-volatile memory cell according to claim 1, wherein the conductive type impurity substrate under the spacer layers has no same doped impurities as forming the source and the drain region.

6. The twin-gate non-volatile memory cell according to claim 2, wherein the substrate comprises an n-well.

7. The twin-gate non-volatile memory cell according to claim 1, wherein the first conductive type impurities are N-type impurities and the second conductive type impurities are P-type impurities.

8. The twin-gate non-volatile memory cell according to claim 7, wherein the substrate comprises a p-well.

9. A method of operating a twin-gate non-volatile memory cell having a first gate, a second gate, non-conductive charge storage layers, a source and a drain, wherein the first gate and the second gate are formed on a second conductive type impurity substrate, the charge-trapping layers are formed on an inner sidewalls of the first gate and the second gate, respectively, and are connected to each other, and the charge-trapping layers store at least one bit of data, the source and the drain are doped first conductive type impurity regions formed in the second conductive type impurity substrate and outside and underneath an edge of the first gate and the second gate, respectively, and the method comprises using Source-Side induced hot carriers Injection (SSI) to inject carriers into the charge-storage layers.

10. The method of operating the twin-gate non-volatile memory cell according to claim 9, wherein the first conductive type impurities are P-type impurities and the second conductive type impurities are N-type impurities, and a method of programming the twin-gate non-volatile memory cell comprises:
applying a first voltage to the substrate; applying a second voltage, which is negative with respect to the substrate, to the drain; applying a third voltage, which is negative with respect to the substrate, to the first gate so as to form a conductive channel under the first gate; applying a fourth voltage, which is negative with respect to the substrate, to the second gate so as to form a conductive channel under the second gate; and, applying a fifth voltage, which does not form a junction forward bias with the substrate, to the source, wherein the settings of the first voltage, the second voltage, the third voltage, the fourth voltage and the fifth voltage are able to initiate a SSI effect so as to inject carriers into the charge-storage layers.

11. The method of operating the twin-gate non-volatile memory cell according to claim 9, wherein the first voltage is about 0V, the second voltage is about −5V, the third voltage is about −1.5V, the fourth voltage is about −5V, and the fifth voltage is about 0V.

12. The method of operating the twin-gate non-volatile memory cell according to claim 10, wherein a sixth voltage identical to the substrate voltage is applied to the drain and a seventh voltage, which does not form a junction forward bias with the substrate, is applied to the drain when the twin-gate non-volatile memory cell is not being selected for programming.

13. The method of operating the twin-gate non-volatile memory cell according to claim 10, wherein reading data from the twin-gate non-volatile memory cell comprises applying an eighth voltage to the substrate; applying a ninth voltage, which is negative with respect to the substrate, to the drain; applying a tenth voltage, which is negative with respect to the substrate, to the first gate so as to form a conductive channel under the first gate; applying an eleventh voltage, which is negative with respect to the substrate, to the second gate so as to form a conductive channel under the second gate; applying a twelfth voltage, which does not form a junction forward bias with the substrate, to the source; wherein the settings of the eighth voltage, the ninth voltage, the tenth voltage, the eleventh voltage and the twelfth voltage do not initiate the SSI effect.

14. The method of operating the twin-gate non-volatile memory cell according to claim 13, wherein the eighth voltage is about 0V, the ninth voltage is about −1.5V, the tenth voltage is about −2.5V, the eleventh voltage is about −2.5V and the twelfth voltage is about 0V.

15. The method of operating the twin-gate non-volatile memory cell according to claim 10, wherein erasing data from the twin-gate non-volatile memory cell comprises initiating a Fowler-Nordheim (FN) erasing operation to drive electrons out of the charge-storage layers.

16. The method of operating the twin-gate non-volatile memory cell according to claim 15, wherein the FN erasing operation comprises floating the source and the drain; applying a thirteenth voltage to the substrate; applying a fourteenth voltage, which is negative with respect to the substrate, to the first gate; and, applying a fifteenth voltage, which is negative with respect to the substrate, to the second gate, wherein settings of all the electrode voltages are able to initiate the FN erasing operation so as to drive the electrons out of the charge-storage layers.

17. The method of operating the twin-gate non-volatile memory cell according to claim 16, wherein the thirteenth voltage is about 5V, the fourteenth voltage is about −5V and the fifteenth voltage is about −5V.

18. The method of operating the twin-gate non-volatile memory cell according to claim 9, wherein the first conductive type impurities are N-type impurities and the second conductive type impurities are P-type impurities, and a programming method comprises:
applying a first voltage to the substrate; applying a second voltage, which is positive with respect to the substrate, to the drain; applying a third voltage, which is positive with respect to the substrate, to the first gate so as to form a conductive channel under the first gate; applying a fourth voltage, which is positive with respect to the substrate, to the second gate so as to form a conductive channel under the second gate; and, applying a fifth voltage, which does not form a junction forward bias with the substrate, to the source, wherein the settings of the first voltage, the second voltage, the third voltage, the fourth voltage and the fifth voltage are able to initiate a SSI effect so as to inject carriers into the charge-storage layers.

19. The method of operating the twin-gate non-volatile memory cell according to claim 18, wherein the first voltage is about 0V, the second voltage is about 5V, the third voltage is about 1.5V, the fourth voltage is about 5V, and the fifth voltage is about 0V.

20. The method of operating the twin-gate non-volatile memory cell according to claim 18, wherein a sixth voltage identical to the substrate voltage is applied to the drain and a seventh voltage, which does not form a junction forward bias with the substrate, is applied to the drain when the twin-gate non-volatile memory cell is not being selected for programming.

21. The method of operating the twin-gate non-volatile memory cell according to claim 18, wherein reading data from the twin-gate non-volatile memory cell comprises applying an eighth voltage to the substrate; applying a ninth voltage, which is positive with respect to the substrate, to the drain; applying a tenth voltage, which is positive with respect to the substrate, to the first gate so as to form a conductive channel under the first gate; applying an eleventh voltage, which is positive with respect to the substrate, to the second gate so as to form a conductive channel under the second gate; and, applying a twelfth voltage, which does not form a junction forward bias with the substrate, to the source, wherein the settings of the eighth voltage, the ninth voltage, the tenth voltage, the eleventh voltage and the twelfth voltage do not initiate the SSI effect.

22. The method of operating the twin-gate non-volatile memory cell according to claim 21, wherein the eighth voltage is about 0V, the ninth voltage is about 1.5V, the tenth voltage is about 2.5V, the eleventh voltage is about 2.5V and the twelfth voltage is about 0V.

23. The method of operating the twin-gate non-volatile memory cell according to claim 18, wherein erasing data from the twin-gate non-volatile memory cell comprises initiating a Fowler-Nordheim (FN) erasing operation to drive electrons out of the charge-storage layers.

24. The method of operating the twin-gate non-volatile memory cell according to claim 23, wherein the FN erasing operation comprises floating the source and the drain, applying a thirteenth voltage to the substrate, applying a fourteenth voltage, which is negative with respect to the substrate, to the first gate, applying a fifteenth voltage, which is negative with respect to the substrate, to the second gate, wherein settings of all the electrode voltages are able to initiate the FN erasing operation so as to drive the electrons out of the charge-trapping layers.

25. The method of operating the twin-gate non-volatile memory cell according to claim 24, wherein the thirteenth voltage is about +5V, the fourteenth voltage is about −5V and the fifteenth voltage is about −5V.
